(19) United States
(12) Patent Application Publication
(10) Pub. No.: US 2026/0371929 A1
(43) Pub. Date: Nov. 19, 2026

(54) MICROPUMP AND METHOD OF FABRICATING THE SAME

(71) Applicant: AITA BIO INC., New York, NY (US)

(72) Inventors: Jacob Menture, New York, NY (US); Peter Smeys, San Jose, CA (US); Dilan Casanovas Mack, New York, NY (US); Laurence Heads, Las Vegas, NV (US)

(21) Appl. No.: 19/639,254

(22) Filed: Apr. 5, 2026

Related U.S. Application Data
(63) Continuation of application No. 17/779,473, filed on Nov. 24, 2020, now Pat. No. 12,610,742.
(60) Provisional application No. 62/940,191, filed on Nov. 25, 2019.

(51) Int. Cl. H10N 30/20; H10N 30/082; H10N 30/09

(52) U.S. Cl. CPC H10N 30/2047; H10N 30/082; H10N 30/09

(57) ABSTRACT

A method is disclosed of fabricating a MEMS device that includes one or more wafers configured as pump or valve. The pump or valve includes an inlet port to receive fluid and an outlet port to release the fluid within the pump or valve. The method comprises growing silicon dioxide on a silicon layer of the one or more wafers to form a silicon dioxide layer on the silicon layer, depositing silicon nitride on the silicon dioxide layer of the one or more wafers to form a silicon nitride layer on the silicon dioxide layer, spinning a front side to create a pattern thereon defining an area for the pump or valve, dry etching the one or more wafers at the area for the pump or valve to remove the silicon dioxide and silicon nitride layers to define an opening for the pump or valve, and wet etching the silicon layer to remove the silicon dioxide and silicon nitride layers at the area to create a membrane for the pump or valve to thereby displace the fluid or prevent fluid flow within the pump or valve.

### CROSS-REFERENCE TO RELATED APPLICATIONS

This application is a continuation of application Ser. No. 17/779,473, filed May 24, 2022 which claims priority to U.S. provisional application No. 62/940,191, filed Nov. 25, 2019 which is incorporated by reference herein.

### FIELD OF THE INVENTION

The present invention relates to a micropump and a method of fabricating the same.

### BACKGROUND OF THE INVENTION

Various infusion systems exist that utilize devices for delivering liquid medication or other therapeutic fluid to patients subcutaneously. For patients with diabetes mellitus, for example, conventional infusion systems incorporate various pumps that are used to deliver insulin to a patient. These pumps have the capability of delivering assorted fluid delivery profiles which include specified basal rates and bolus requirements. For example, these pumps include a reservoir to contain the liquid medication along with electromechanical pumping technology to deliver the liquid medication via tubing to a needle that is inserted subcutaneously into the patient.

Although such conventional pumps/infusion systems are adequate for their intended purpose, there remains a need for an independent, portable pump with low power consumption to simplify the set up and assembly of these systems. There is also a need to provide an improved method of fabricating these systems.

### SUMMARY OF THE INVENTION

A micropump and method of fabricating the micropump are disclosed.

In accordance with an embodiment of the present disclosure, a method is disclosed of fabricating a MEMS device that includes one or more wafers configured as pump or valve, the pump or valve includes an inlet port to receive fluid and an outlet port to release the fluid within the pump or valve, the method comprising: growing silicon dioxide on a silicon layer of the one or more wafers to form a silicon dioxide layer on the silicon layer; depositing silicon nitride on the silicon dioxide layer of the one or more wafers to form a silicon nitride layer on the silicon dioxide layer; spinning a front side of the one or more wafers to create a pattern thereon defining an area for the pump or valve; dry etching the wafer at the area for the pump or valve to remove the silicon dioxide and silicon nitride layers to define an opening for the pump or valve; and wet etching the silicon layer to remove the silicon dioxide and silicon nitride layers at the area to create a membrane for the pump or valve to thereby displace the fluid or prevent fluid flow within the pump or valve.

In accordance with an embodiment of the present disclosure, a method is disclosed of fabricating a MEMS device that includes one or more wafers configured as pump or valve, the pump or valve includes an inlet port to receive fluid and an outlet port to release the fluid within the pump or valve, the method comprising, the method comprising: growing silicon dioxide on a silicon layer of the one or more wafers to form a silicon dioxide layer on the silicon layer; depositing silicon nitride on the silicon dioxide layer of the one or more wafers to form a silicon nitride layer on the silicon dioxide layer; spinning a front side of the wafer to create a pattern thereon defining an area for the pump or valve; dry etching the wafer at the area for the pump or valve to remove the silicon dioxide and silicon nitride layers to define an opening for the pump or valve; and wet etching the silicon layer to remove the silicon dioxide and silicon nitride layers at the area to create inlet and outlet openings of the one or more wafers.

In accordance with an embodiment of the present disclosure, a method is disclosed of fabricating a MEMS device that includes first and second wafers configured together as a pump or valve, the pump or valve includes an inlet port to receive fluid, an outlet port to release the fluid within the pump or valve and a chamber, communicating with the inlet port and outlet port, for storing the fluid within the pump or valve, the method comprising: growing silicon dioxide on a silicon layer of the first wafer to form a silicon dioxide layer on the silicon layer; depositing silicon nitride on the silicon dioxide layer of the first wafer to form a silicon nitride layer on the silicon dioxide layer; spinning a front side of the first wafer to create a pattern thereon defining an area for the pump or valve; dry etching the first wafer at the area for the pump or valve to remove the silicon dioxide and silicon nitride layers to define the opening for the pump or valve; wet etching the silicon layer of the first wafer to remove the silicon dioxide and silicon nitride layers at the area to create a membrane for the pump or valve to thereby displace the fluid within the chamber or prevent fluid flow from moving through the inlet port, the chamber and the outlet port within the pump or valve; and growing silicon dioxide on a silicon layer of the second wafer to form a silicon dioxide layer on the silicon layer; depositing silicon nitride on the silicon dioxide layer of the second wafer to form a silicon nitride layer on the silicon dioxide layer; spinning a front side of the second wafer to create a pattern thereon defining an area for the pump or valve; dry etching the second wafer at the area for the pump or valve to remove the silicon dioxide and silicon nitride layers to define an opening for the pump or valve; wet etching the silicon layer to remove the silicon dioxide and silicon nitride layers at the area to create inlet and outlet openings of the second wafer; bonding the first and second wafers to define the chamber of the pump chamber or valve; and mounting piezoelectric actuators in the membrane of the pump or valve.

In accordance with an embodiment of the present disclosure, a cavity substrate is disclosed of a MEMS device configured as a pump or valve with an inlet port to receive fluid and an outlet port release the fluid within the pump or valve, the substrate comprising: first and second silicon layers, the first layer configured as a membrane; and a chamber defined by the layers for receiving fluid, configured to communicate with the inlet and outlet ports, the chamber further configured in a rectangular or oblong shape, wherein the second layer configured to support the membrane over the chamber, to thereby enable the membrane to move fluid from the chamber or prevent the fluid from moving through the chamber.

In accordance with an embodiment of the present disclosure, a method is disclosed of fabricating cavity substrate of a MEMS device that is configured as a valve with an inlet port to receive fluid and an outlet port to release the fluid within the valve, the method comprising: depositing silicon dioxide onto a silicon layer to form a silicon dioxide layer; patterning and etching the silicon dioxide layer using lithography and plasma etch to create a height of the valve; patterning and etching the silicon layer to form a valve seat and a chamber of the cavity substrate; patterning and etching the silicon layer to create the inlet and outlet ports of the cavity substrate; fusion bonding a silicon on insulator wafer to the cavity substrate; removing a handle wafer to expose the silicon layer as a membrane; depositing a piezoelectric stack on silicon oxide layer, the piezoelectric stack includes a piezoelectric element and an electrode layer between the piezoelectric element and the silicon dioxide layer; pattering and etching the piezoelectric (PZT) element; patterning and etching the electrode layer up to the silicon dioxide layer; depositing an interlayer dielectric layer (ILD) or passivation layer; patterning the interlayer dielectric layer until it reaches the electrode layer and piezoelectric element; depositing and patterning the electrode layer on top of the piezoelectric element and pads on bottom electrode layer; electroplating gold pads are electroplated; and back grinding, etching and polishing the silicon layer short of the opening in the silicon layer.

### BRIEF DESCRIPTION OF DRAWINGS

FIG. 1 depicts a cross sectional view of an example pump.

FIG. 2 depicts a cross sectional view of an example valve.

FIG. 3 depicts a top cross sectional view of an example pump in series with two valves.

FIG. 4 depicts a top cross sectional view of several example pumps in series with active valves.

FIG. 5 depicts a top cross sectional view of another example pump.

FIGS. 6 and 7 depict examples of two pumps.

FIGS. 8-22 depict several stages and steps of valve fabrication and corresponding structure.

FIGS. 23-39 depict several stages and steps of another pump and valve fabrication along with the corresponding pump and valve structure.

### DETAILED DESCRIPTION OF THE INVENTION

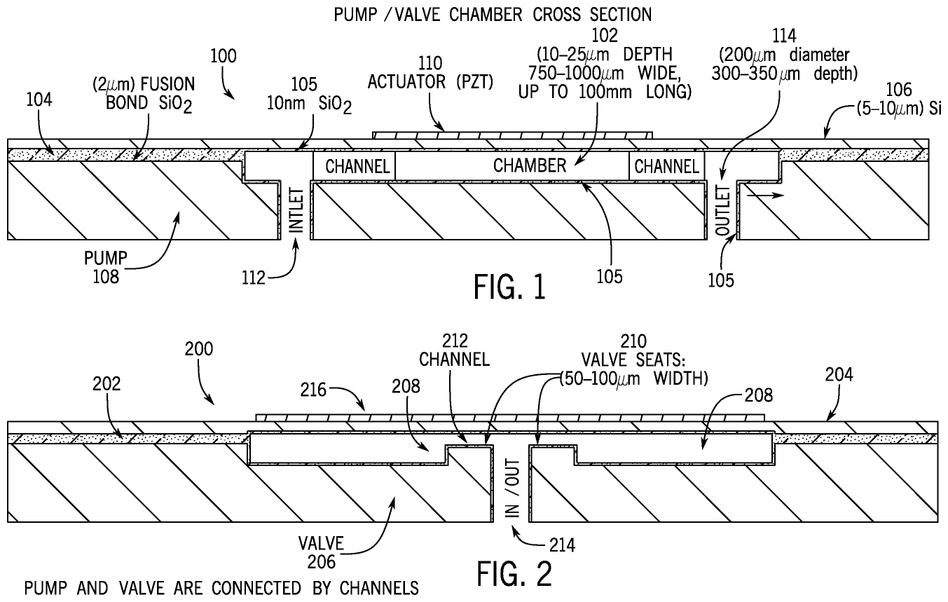

FIG. 1 depicts a cross sectional view of an example pump 100 as a micropump. Pump 100 is a MEMS (micro-electro-mechanical systems) device, as known to those skilled in the art, that can be used for pumping fluid, valves used for regulating flow, actuators used for moving or controlling the pump and valves and sensor used for sensing pressure. The MEMS device incorporates a piezoelectric transducer as known to those skilled in the art. (However, the MEMS devices may include a capacitive transducer or piezoresistive transducer) that acts as the active element for pumping fluid, but other MEMS structures or technology may be used to achieve desired results as known to those skilled in the art.). Pump 100 may be used in a drug infusion system for infusing a drug (i.e., medication) or other fluid to a patient (user). Medication may include small molecule pharmaceutical solutions, large molecule or protein drug solutions, saline solutions, blood or other fluids known to those skilled in the art. Insulin is an example fluid. However, pump 100 may be used in other environments known to those skilled in the art.

Pump 100 is configured to maximize pump efficiency per mm² (i.e., stroke volume per unit area per Watt). To this end, pump 100 is a cavity substrate that incorporates a chamber or cavity 102 that is configured as rectangular or oblong shaped, but it can be alternatively shaped as an elliptical, fillet, circular, square or other shaped pump cell known to those skilled in the art to achieve desired results. The structure and benefits of this chamber are described in detail below. (Note measurements shown in FIGS. 1-39 and described herein are example measurements. Those skilled in the art know that other values may be used for such measurements.)

Structurally, a silicon dioxide (SiO₂) layer 104 sits between silicon (Si) layers 106 and 108 as shown. Silicon dioxide layer 104 is used to fusion bond the silicon layers 106 and 108 (process details below). However, other techniques may be used to bond the silicon layers 106 and 108 as known to those skilled in the art. Silicon dioxide layer 105 lines the surface of chamber 102 as well as channels and inlet and outlet ports 112, 114 as shown. Chamber 102 communicates with inlet and outlet openings 112, 114 via the channels. Silicon layer 106 covers chamber 102 act upon the fluid within chamber 102 (i.e., to pump fluid—displace or draw fluid).

Silicon layer 106 functions as the membrane of the cavity substrate as known to those skilled in the art. Piezoelectric actuator 110 is layered on top of silicon layer 106 and it functions to pump or deform/bend silicon layer 106 to draw into or displace liquid contents from chamber 102 as known to those skilled in the art. It is the shape of the silicon layers 106 (and 206 below), i.e., the walls, along with the silicon dioxide layer 104 that define the shape of chamber 102 described hereinabove and the shape of inlet and outlets 112 and 114.

As indicated above, chamber 102 is configured as pump chamber (also known as a cavity or pump cell) that has a preferable width in the range of 200 μm-1 mm and a length of up to 10 mm, but other widths and lengths may be used as known to those skilled in the art. The maximum chamber 102 width is limited by manufacturing constraints (allowed sag, bow). By using a shaped cell as described hereinabove, area efficiency, i.e., fill factor—pump chamber (or valve chamber—below) area/total area, increases (over circular membranes) is optimized to reduce dead volume of the pumping chamber, with very little trade-off in reduction to stroke volume. This results in a larger compression ratio for the micropump and a larger per unit area and per watt of actuation power as known to those skilled in the art. To achieve the same net pumping efficiency with a rectangular or square piezoelectric chamber shape, more dead space (e.g., approximately 60-65% for rectangular as opposed to 80-85% packing efficiency for hexagonal piezoelectric transducer) must be incurred, and thus a lower compression ratio for the overall pump. Pump chambers (i.e., cavities or cells) may be arrayed in parallel or in series to increase total stroke volume.

As for fabrication (in brief), pump chamber 102 is completely sealed until the very last step in the fabrication process, thereby minimizing the propensity for defect or particle introduction during processing. That is, the pump and channels remain closed until the very end of fabrication processing. This is accomplished by dividing the final pump wafer thinning into two steps: a wafer grind/polish to within 25 μm of the inlet/outlet and a final blanket dry etch step to open up the inlet/outlet. This entire process is described in more detail below.

FIG. 2 depicts a cross sectional view of an example valve 200 (MEMS device). Valve 200 is also a cavity substrate that incorporates a silicon dioxide layer 202 between silicon layers 204 and 206 as shown. The silicon dioxide layer 202 is used to fusion bond the silicon layers 204 and 206 as described in more detail below. Silicon layer 204 functions as the membrane of the cavity substrate as known to those skilled in the art. Similar to the structure of pump 100 above, the shape of silicon layer 206 along with silicon oxide layer 202 define the shape of chamber 208 (or cavity) as a desired pump cell as described above.

Valve 200 includes two valve seats 210 that are defined by the shape of silicon layer 206 and silicon oxide layer 202 (liner). Valve seats 210 are configured to extend into chamber 208 and to define channel 212 and inlet/outlet 214. Piezoelectric actuator 216 is layered on top of silicon layer 204. Actuator 216 compresses against silicon layer 110 (membrane) to reach and seal valve seats 210 to discontinue flow through inlet/outlet 214 as known to those skilled in the art. (Note that a micropump may include any number of pumps and/or valves as described herein.)

Importantly, the fusion bond silicon oxide layer 202 thickness is configured to define the valve seat height (FIG. 9—Mask 1 in process flow below). The fusion bond silicon oxide is a thermally grown oxide that can be controlled very precisely (<3% total variation) from batch to batch. The silicon oxide is removed using a dry or wet etch in the active portion of the valve. The thickness of the silicon oxide will determine the clearance between the membrane and the valve seat.

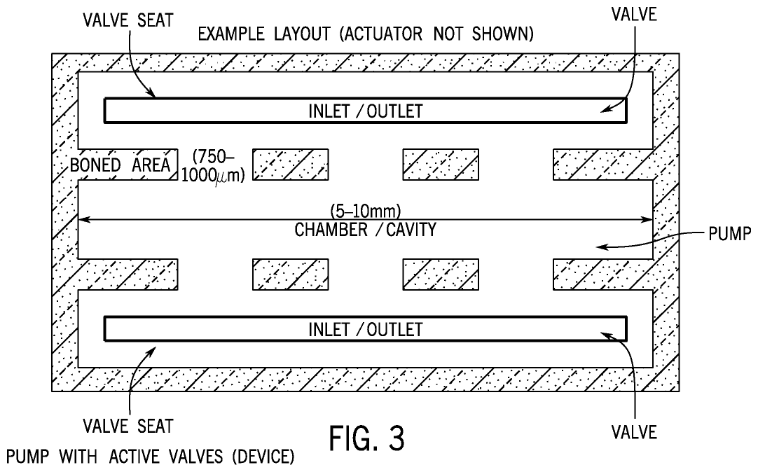

FIG. 3 depicts a top cross sectional view of an example pump in series with two valves (layout in horizontal view). Specifically, there is one pump chamber (cavities or cells) connected to two active inlet/outlet valves. Each chamber (cavities or cell) has its own actuator (not shown). The valves also have actuators (not shown) as well as valve seats.

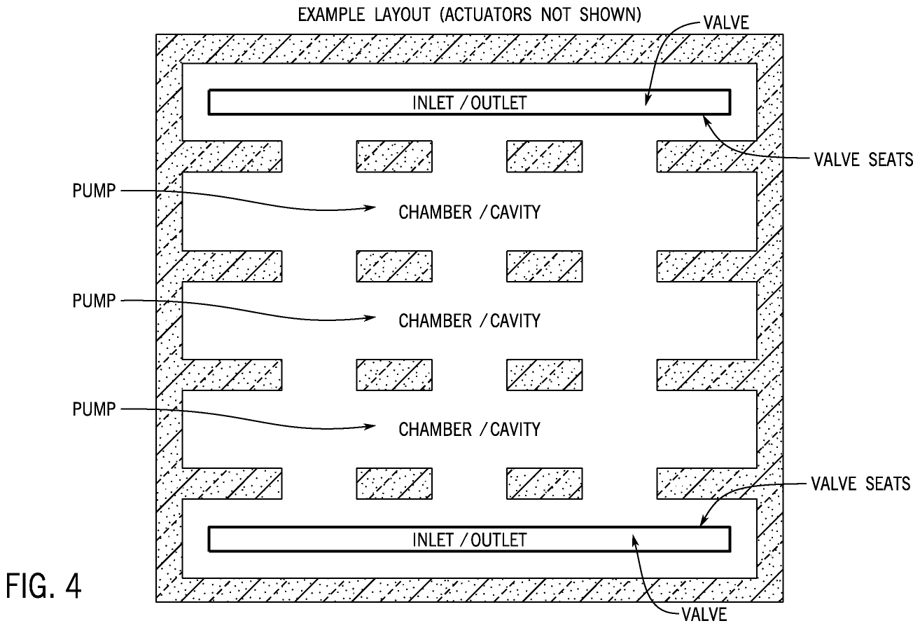

FIG. 4 depicts a top cross sectional view of several pumps (cells) in series with active valves. Specifically, three pumps are configured in series, each which includes a chamber along with an actuator (not shown). There are a total of three actuators for the pump (cells). Each inlet/outlet valve has its own actuator (not shown) as well as valve seats as shown.

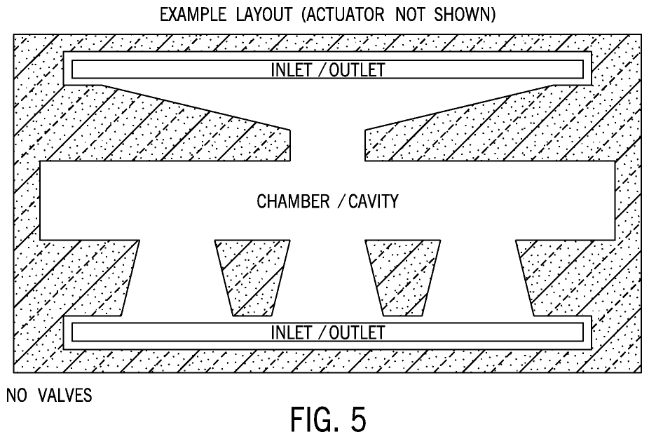

FIG. 5 depicts a top cross sectional view of another example pump (positioned horizontally for viewing). This configuration has no valves. An actuator is configured over the chamber/cavity (not shown). The chamber shown leads to several funnels down to inlet/outlets. The funnels are shaped in such a way to create a rectifying flow behavior.

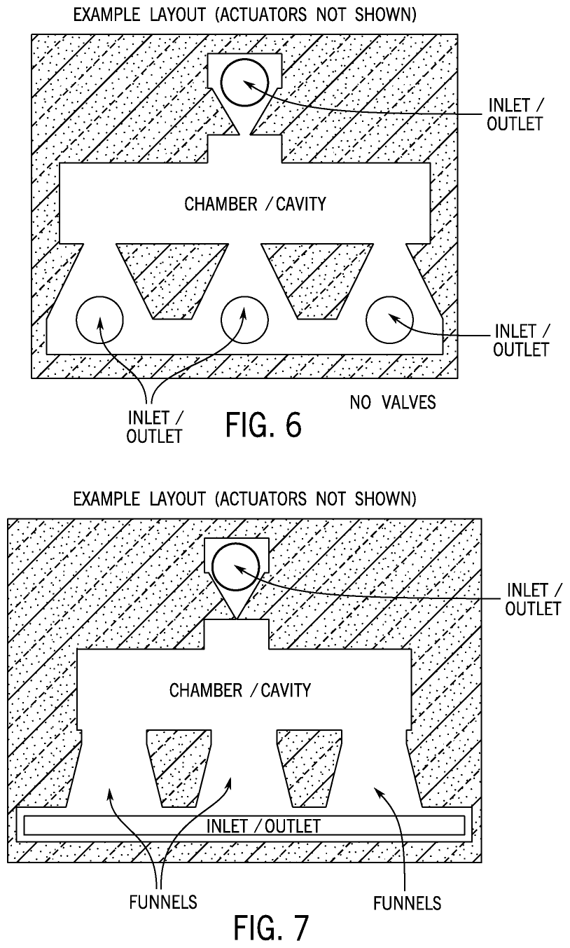

FIGS. 6 and 7 depict examples of two other pumps. In FIG. 6, a chamber communicates with several funnels that lead down to circular inlet and outlets. Actuators are used but not shown. In FIG. 7, the chamber leads to several funnels to a rectangular inlet/outlets. In the configurations with rectangular inlet/outlets, the pump is less prone to blocking due to air bubbles or particles.

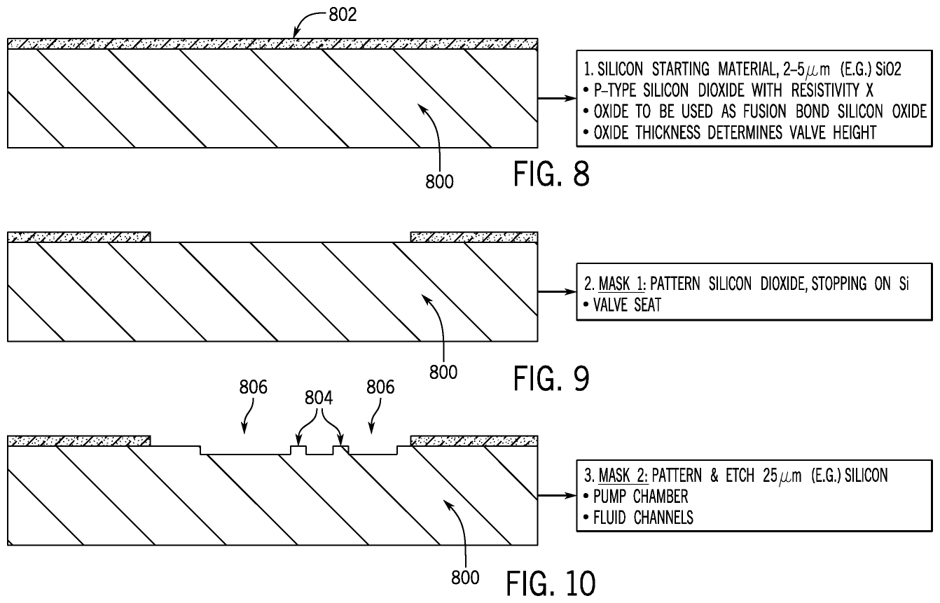

FIGS. 8-22 depict several stages and steps of valve fabrication along with the corresponding valve structure. Cavity silicon on insulator substrate (CSOI) is initially created. To this end, the process proceeds to step 1 wherein a silicon material 800 is the starting material used to form a first silicon layer. Silicon dioxide is deposited onto silicon layer 800 to form a silicon dioxide layer 802 (SiO₂) as shown in FIG. 8. Approximately 2-5μm of silicon dioxide may be used, but other measurements are possible as known by those skilled in the art. Note that the silicon dioxide thickness impacts valve height when in the open position.

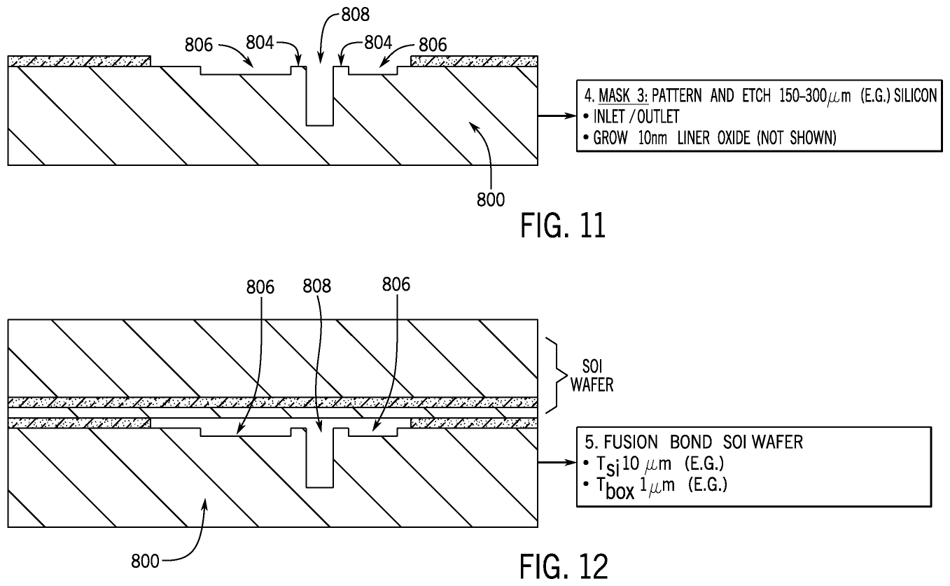

The process proceeds to step 2 wherein silicon dioxide is patterned and etched, stopping at the silicon (using lithography and plasma etch) to create a valve height as shown in FIG. 9. At step 3, silicon layer 800 is patterned and etched to 5-20 μm (for example) to form a valve seat 804 and a chamber 806 as shown in FIG. 10. The process proceeds to step 4 wherein the silicon layer is patterned and etched approximately 150-300 μm (e.g.) to create inlet/outlet ports 808 or vias as shown in FIG. 11. A 10 nm (e.g.) silicon dioxide liner for the chamber and channels is grown (not shown).

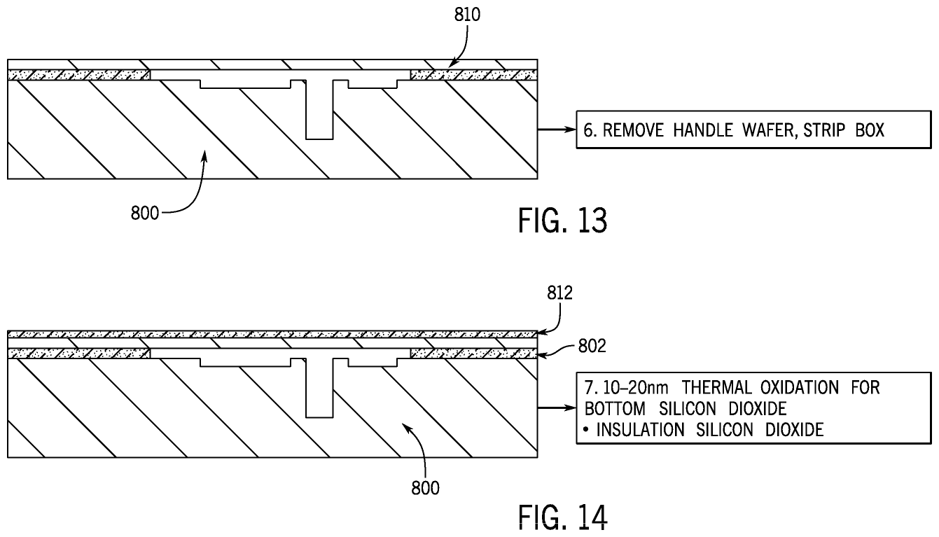

The process then proceeds to step 5 wherein a silicon on insulator wafer (SOI) is fusion bonded to the resulting patterned substrate as shown in FIG. 12. A thickness for the silicon may be 10 μm (for example) and the thickness of the buried oxide (BOX) may be 1 μm (e.g.). Next, the process proceeds to step 6 wherein the handle wafer is removed to expose the silicon (Si) membrane 810 as shown in FIG. 13.

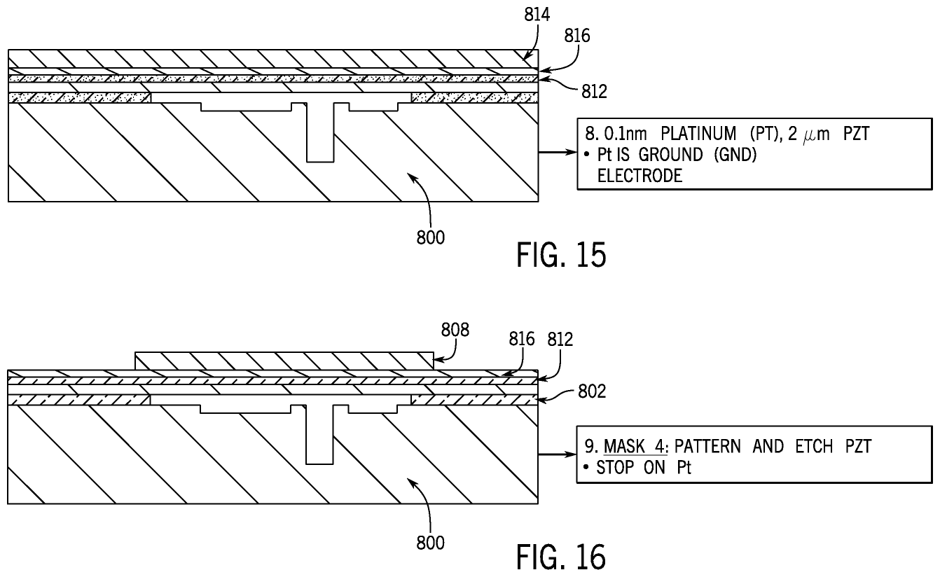

The process proceeds to step 7 wherein an isolation silicon oxide (e.g., 10-20 nm, thermal) layer 812 is grown on the membrane 810 as shown in FIG. 14. The process proceeds to step 8 wherein a piezoelectric stack is deposited on layer 812 as shown in FIG. 15. The piezoelectric stack includes a piezoelectric element 814 and an electrode layer 816 between the piezoelectric element 814 and the silicon dioxide layer 812. The electrode layer is a 0.1 μm (e.g.) of platinum (Pt) which will be configured as a ground (GND) electrode. Then, at step 9, the piezoelectric (PZT) element 814 is patterned and etched at step at FIG. 16, but etching stops at the electrode layer 816.

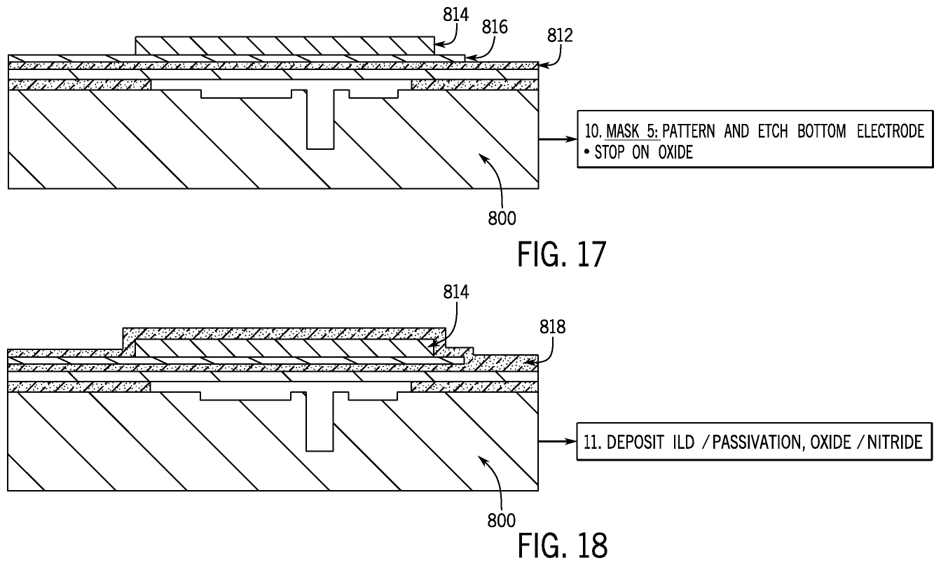

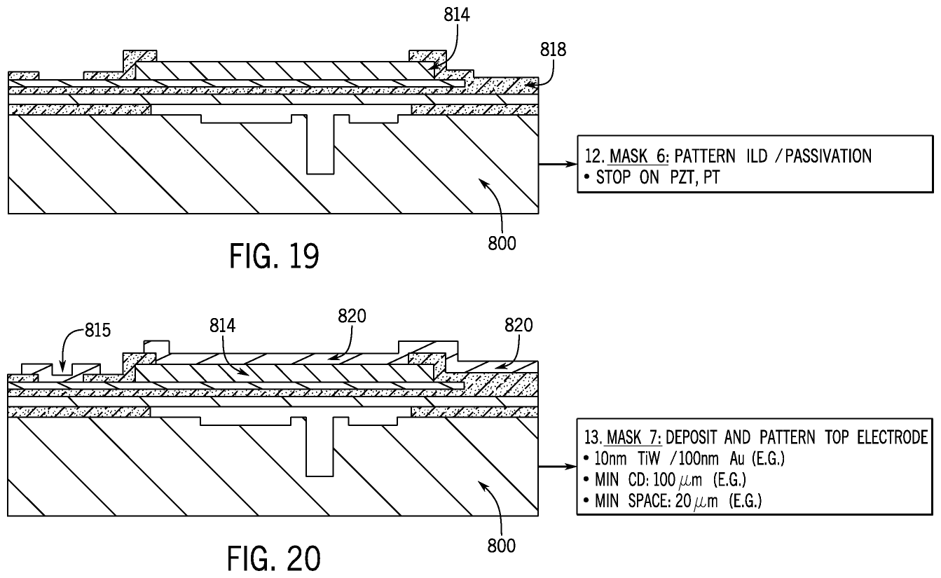

The process proceeds to step 10 wherein electrode layer 816 is patterned and etched, up to the silicon dioxide layer 812 as shown in FIG. 17 and then proceeds to step 11 wherein an interlayer dielectric layer (ILD) 818 or passivation is deposited (thickness 400 nm, e.g. as shown in FIG. 18. The process proceeds to step 12 wherein the interlayer dielectric 818 is patterned until it reaches electrode layer 816 and piezoelectric material 814 as shown in FIG. 19.

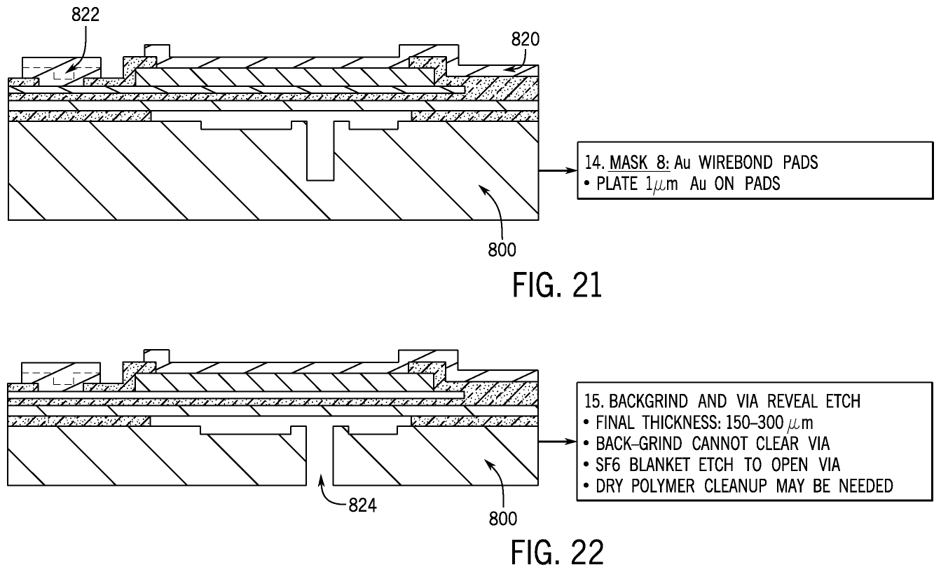

The process proceeds to step 13 wherein an electrode 820 is deposited and patterned on top of piezoelectric (PZT) element 814 and pads 815 on bottom electrode layer 816 as shown in FIG. 20. Top electrode 820 may comprise 10 nm Titanium Tungsten (TiW) and 100 nm of gold (Au) for example. The process then proceeds to step 14 wherein gold (Au) pads 822 are electroplated to 1 μm (e.g.) as shown in FIG. 21. Then, the process concludes with step 15 wherein silicon layer 800 is back-grinded, etched and polished approximately 15μm short of the opening 824 (VIA). This is shown in FIG. 22. Dry polymer cleanup may be used as needed. These steps are described with respect to valve fabrication. However, the same process steps are used for pump fabrication.

As described, the chamber of the substrate is completely sealed until the very last step 15 in the process above, therefore minimizing the propensity for defect introduction (contamination). This is done by dividing the final wafer thinning step into two steps. First, a wafer is grinded/polished to within 25 μm (e.g.) of the inlet/outlet and (final) blanket dry etched step to open up the inlet/outlet. This significantly reduces contamination in the chamber/fluid path from wet chemical processes.

As indicated above, the measurements in these figures and described herein are examples values for several parameters. However, those skilled in the art know that other values may be used to achieve desired results.

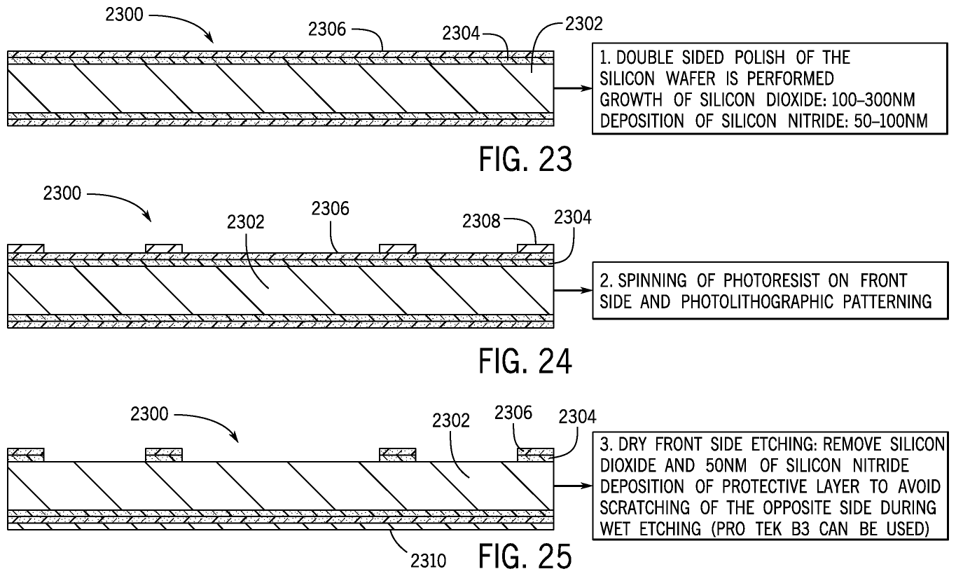

FIGS. 23-39 depict several stages and steps of another pump and valve fabrication along with the corresponding pump and valve structure. (These figures are in cross-section.). The pump or valve is a cavity substrate that includes a top wafer and a bottom wafer. The fabrication process is split between the top wafer and the bottom wafer before they are bonded together. FIGS. 23-29 depict the fabrication process of the top wafer, FIG. 30-36 depict the fabrication process of the bottom wafer, and FIG. 37-39 depict the bonding process and mounting of the piezo actuators. Both top and bottom wafers are silicon wafers with a thickness of approximately 525 μm.

The process proceeds to step 1 for the top wafer 2300 fabrication wherein a silicon material 2302 is the starting material used to for a first silicon layer. A double sided polishing is performed on the initial silicon wafer followed by the growth of a silicon dioxide to form a silicon dioxide layer 2304 (SiO₂) as shown in FIG. 23. A silicon dioxide layer thickness of 100-300 nm may be created, but other thickness measurements are possible as known by those skilled in the art. Subsequently, silicon nitride is deposited on the silicon dioxide layer 2304 to form a silicon nitride layer 2306 as also shown in FIG. 23. Silicon nitride layer 2306 thickness of 50-100 nm may be used, but other measurements are possible as known by those skilled in the art. The same layering appears on the opposing side as shown.

The process proceeds to step 2 wherein spinning of photoresist and photolithographic patterning 2308 on the front side (of the top/first wafer) are completed for assisting in the creation of (i.e., its definition) the valve and pump diaphragm (membrane) by defining openings (i.e., markers as a guide for subsequent etching as described below) as shown in FIG. 24. At step 3, silicon dioxide layer 2304 and silicon nitride 2406 layers are removed by dry etching at the valve and pump openings as shown. Additionally, a protective layer 2310 is applied to avoid scratching the backside of the wafer during wet etching as shown in FIG. 25. This material can be Pro TEK B3, but other materials may be used instead as known to those skilled in the art.

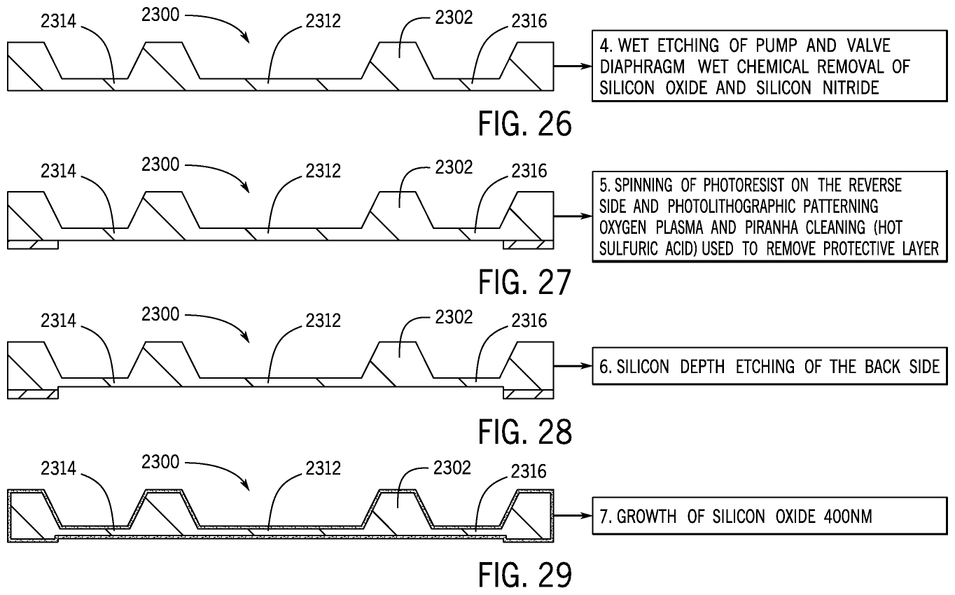

The process proceeds to step 4 wherein the wet etching is performed on silicon layer 2300 to create the diaphragms (membranes) for the pump 2312 and valves 2314, 2316 followed by a wet chemical removal of silicon oxide and silicon nitride as shown in FIG. 26. Furthermore, oxygen plasma and piranha cleaning (hot sulfuric acid) are applied to remove protective layer 2310. The depth of the etching is set by the time control of the etching process. The thickness of the pump and valve diaphragm (membrane) can be 30-50 μm, but other measurements are possible as known by those skilled in the art.

As described, wet etching on the base silicon wafer 2300 creates the three different diaphragms 2312, 2314, 2316 in this example for the inlet, pump and outlet valves. The wet etching is performed at a selected temperature (e.g., 60 degrees Celsius) known to those skilled in the art. The amount etched is dependent on the time allowed for etching. In addition, etching three different membranes for example (or any number thereof) with a thicker silicon structure provides increases pump structure solidity or firmness in between the membranes. This improved solid structure helps avoid coupling. During coupling, as known to those skilled in the art, two membranes vibrate despite lack of activation when the piezoelectric actuator and corresponding membrane are actuated.

The process proceeds to step 5 wherein a spinning of photoresist and photolithographic patterning on the back side are done for assisting in the creation of a definition for the opening (as a guide for subsequent etching as described below) of the top side of the pump and valve chambers as shown in FIG. 27. At step 6, silicon depth etching is performed on the back side of wafer 2300 to define the top of the pump and valve chambers as shown in FIG. 28.

The process proceeds to step 7, wherein wet chemical removal of the photoresist is done followed by growing a silicon dioxide layer on the outside perimeter of the remaining silicon wafer as shown in FIG. 29. The silicon dioxide layer thickness can be 200-400 nm, but other measurements are possible as known by those skilled in the art. This completes the fabrication process of top wafer 2300.

The process proceeds to step 8 for the bottom wafer 3000 fabrication wherein a silicon material is the starting material used for a first silicon layer 3002. A double sided polishing is performed on the initial silicon wafer 3002 followed by the growth silicon dioxide to form a silicon dioxide layer 3004 (SiO₂) as shown in FIG. 30. A silicon dioxide layer thickness of 100-300 nm may be used, but other measurements are possible as known by those skilled in the art. Subsequently, silicon nitride is deposited on silicon dioxide layer 3004 to form a silicon nitride layer 3006 as also shown in FIG. 30. A silicon nitride layer thickness of 50-100 nm may be used, but other measurements are possible as known by those skilled in the art. (These silicon dioxide and silicon nitride layers appear on both sides of silicon layer 3002.)

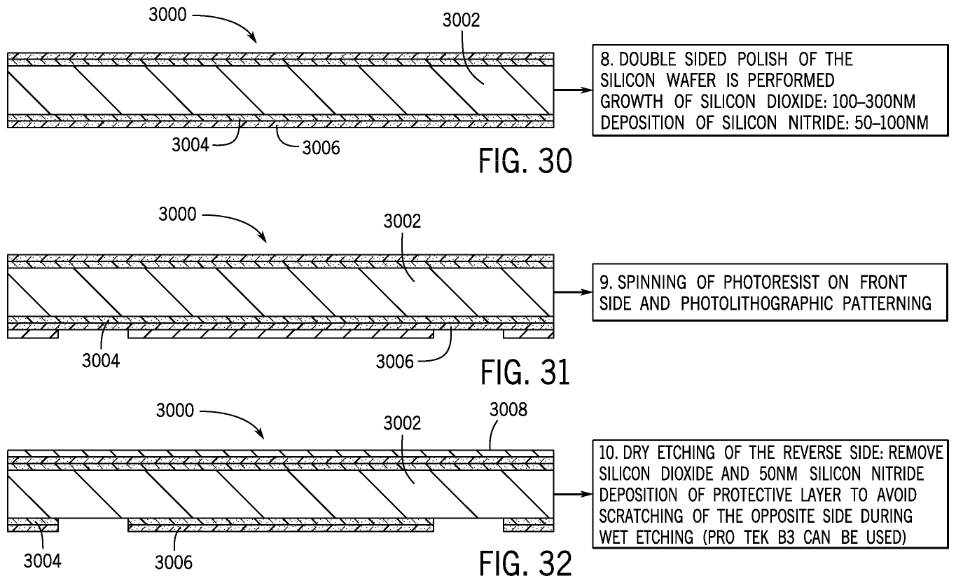

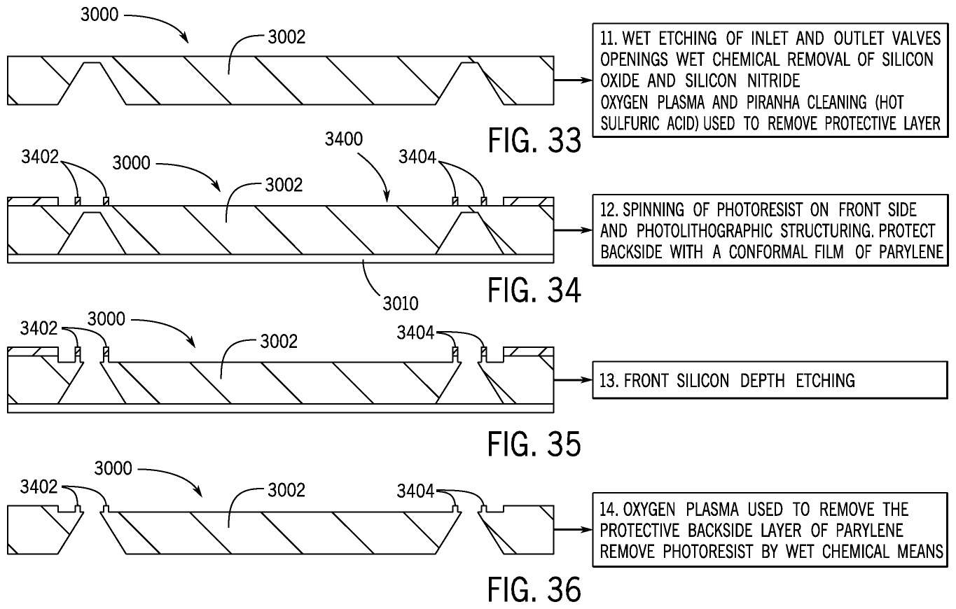

The process proceeds to step 9 wherein spinning of photoresist and photolithographic patterning on the front side are done to for the definition of the inlet and outlet openings as seen in FIG. 31. At step 10, the silicon dioxide layer 3004 and silicon nitride layer 3006 are removed by dry etching at the inlet and outlet openings as shown in FIG. 32. Additionally, a protective layer 3008 to avoid scratching the backside of the wafer during wet etching is applied. This material can be Pro TEK B3. The process proceeds to step 11 wherein the wet etching is performed on silicon layer 3002 to create the inlet and outlet openings of the valves as shown in FIG. 33. Furthermore, oxygen plasma and piranha cleaning (hot sulfuric acid) is used to remove protective layer 3008 as also shown in FIG. 33.

The process proceeds to step 12 wherein a spinning photoresist and photolithographic patterning on the front side for the definition of the bottom of the pump chamber and valve seats 3400, 3402 while the backside is protected with a conformal film of parylene 3010 as shown in FIG. 34.

At step 13, silicon depth etching is performed on the front of the wafer 3000 to define the bottom of the pump and valve chamber 3400 as well as the valve seats 3402, 3404 as shown in FIG. 35. The chamber depth can be 25-40 μm and the valve seats can be 2-30 μm, but other measurements are possible as known by those skilled in the art. The process proceeds to step 14, wherein the protective conformal layer 3010 of parylene is removed with oxygen plasma as well as wet chemical removal of the photoresist as shown in FIG. 36. This completes the fabrication of the bottom wafer.

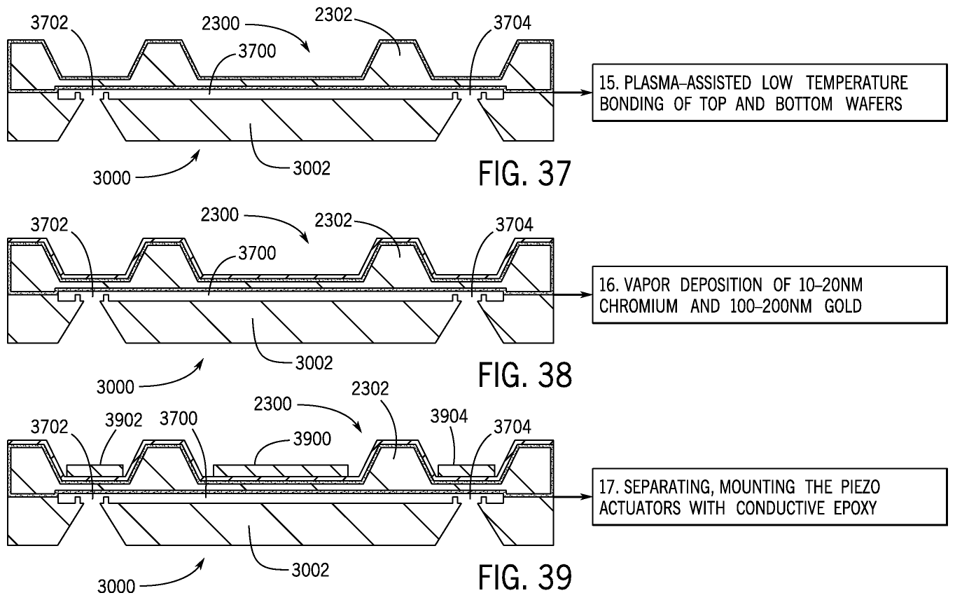

The process proceeds to step 15 wherein plasma-assisted low temperature bonding of top and bottom wafers 2300, 3000 are performed to fully define and completely seal the pump chamber 3700 and valve chambers 3702, 3704 as shown in FIG. 37. At step 16, vapor deposition chromium and gold are performed on the topside as shown in FIG. 38. The thickness of the chromium layers can be 10-20 nm and the thickness of the gold layer can be 100-200 nm, but other measurements are possible as known by those skilled in the art. The process concludes at step 17 wherein the piezoelectric actuators 3900, 3902, 3904 are mounted onto the top side of the pump and valve diaphragms using conductive epoxy as shown in FIG. 39. Piezoelectric actuator functions to pump or deform/bend silicon layer as described above.

The pumps and valves described herein may have many applications in a variety of industries including the medical industry, such as drug delivery, lab-on-a-chip, point of care diagnostics and micro-dosing in industrial control.

It is to be understood that the disclosure teaches examples of the illustrative embodiments and that many variations of the invention can easily be devised by those skilled in the art after reading this disclosure and that the scope of the present invention is to be determined by the claims below.

What is claimed is:

1. A method of fabricating a MEMS device that includes one or more wafers configured as a pump or valve, the pump or valve includes an inlet port to receive fluid and an outlet port to release the fluid within the pump or valve, the method comprising:
growing silicon dioxide on a silicon layer of the one or more wafers to form a silicon dioxide layer on the silicon layer;
depositing silicon nitride on the silicon dioxide layer of the one or more wafers to form a silicon nitride layer on the silicon dioxide layer;
spinning a front side of the one or more wafers to create a pattern thereon defining an area for the pump or valve;
dry etching the one or more wafers at the area for the pump or valve to remove the silicon dioxide and silicon nitride layers to define an opening for the pump or valve; and
wet etching the silicon layer to remove the silicon dioxide and silicon nitride layers at the area to create a membrane for the pump or valve to thereby displace the fluid or prevent fluid flow within the pump or valve.

2. The method of claim 1 further comprising applying a protective layer to a backside of the wafer to avoid damage during the wet etching.

3. The method of claim 1 wherein the spinning is photoresist and photolithographic patterning.

4. The method of claim 2 further comprising removing the protective layer by using oxygen plasma and piranha cleaning.

5. The method of claim 1 further comprising wherein the depth of etching is set by time control.

6. The method of claim 1 further comprising spinning a back side of the one or more wafers to create a pattern for defining an opening on the top side of the pump or valve.

7. The method of claim 6 further comprising etching the back side of the one or more wafers to define a top of the pump or valve.

8. The method of claim 7 wherein the spinning is photoresist and photolithographic patterning.

9. The method of claim 7 further comprising removing photoresist by wet etching.

10. The method of claim 9 further comprising growing a silicon dioxide layer on the outside perimeter of the one or more wafers.

11. A method of fabricating a MEMS device that includes one or more wafers configured as a pump or valve, the pump or valve includes an inlet port to receive fluid and an outlet port to release the fluid within the pump or valve, the method comprising, the method comprising:
growing silicon dioxide on a silicon layer of the one or more wafers to form a silicon dioxide layer on the silicon layer;
depositing silicon nitride on the silicon dioxide layer of the one or more wafers to form a silicon nitride layer on the silicon dioxide layer;
spinning a front side of the wafer to create a pattern thereon defining an area for the pump or valve;
dry etching the wafer at the area for the pump or valve to remove the silicon dioxide and silicon nitride layers to define an opening for the pump or valve; and
wet etching the silicon layer to remove the silicon dioxide and silicon nitride layers at the area to create the inlet and outlet openings of the one or more wafers.

12. The method of claim 11 further comprising applying a protective layer to a backside of the wafer to avoid damage during the wet etching.

13. The method of claim 11 wherein the spinning is photoresist and photolithographic patterning.

14. The method of claim 11 further comprising spinning a front side of the wafer to create a pattern thereon defining a bottom area thereon for a chamber of the pump or the valve.

15. The method of claim 14 further comprising depth etching the front of the wafer to remove the silicon layer to define the bottom of the pump chamber or valve chamber and valves seats.

16. The method of claim 15 further comprising removing the photoresist.

17. A method of fabricating a MEMS device that includes first and second wafers configured together as a pump or valve, the pump or valve includes an inlet port to receive fluid, an outlet port to release the fluid within the pump or valve and a chamber, communicating with the inlet port and outlet port, for storing the fluid within the pump or valve, the method comprising:
growing silicon dioxide on a silicon layer of the first wafer to form a silicon dioxide layer on the silicon layer;
depositing silicon nitride on the silicon dioxide layer of the first wafer to form a silicon nitride layer on the silicon dioxide layer;
spinning a front side of the first wafer to create a pattern thereon defining an area for the pump or valve;
dry etching the first wafer at the area for the pump or valve to remove the silicon dioxide and silicon nitride layers to define the opening for the pump or valve;
wet etching the silicon layer of the first wafer to remove the silicon dioxide and silicon nitride layers at the area to create a membrane for the pump or valve to thereby displace the fluid within the chamber or prevent fluid flow from moving through the inlet port, the chamber and the outlet port within the pump or valve; and
growing silicon dioxide on a silicon layer of the second wafer to form a silicon dioxide layer on the silicon layer;
depositing silicon nitride on the silicon dioxide layer of the second wafer to form a silicon nitride layer on the silicon dioxide layer;
spinning a front side of the second wafer to create a pattern thereon defining an area for the pump or valve;
dry etching the second wafer at the area for the pump or valve to remove the silicon dioxide and silicon nitride layers to define an opening for the pump or valve;
wet etching the silicon layer to remove the silicon dioxide and silicon nitride layers at the area to create inlet and outlet openings of the second wafer;
bonding the first and second wafers to define the chamber of the pump chamber or valve; and
mounting piezoelectric actuators in the membrane of the pump or valve.

18. The method of claim 17 wherein the bonding is assisted by low temperature boding.

19. The method of claim 17 further comprising depositing chromium and gold on the first wafer prior to bonding.

20. The method of claim 17 wherein the spinning is photoresist and photolithographic patterning.

21. The method of claim 17 further comprising wherein the depth of wet etching of the first wafer is set by time control.

22. The method of claim 17 further comprising spinning a back side of the first wafer to create a pattern for defining an opening on the top side of the pump or valve.

23. The method of claim 22 further comprising etching the back side of the first wafer to define a top of the pump or valve.

24. A cavity substrate of a MEMS device configured as a pump or valve with an inlet port to receive fluid and an outlet port release the fluid within the pump or valve, the substrate comprising:
first and second silicon layers, the first layer configured as a membrane; and
a chamber defined by the layers for receiving fluid, configured to communicate with the inlet and outlet ports, the chamber further configured in a rectangular or oblong shape, wherein the second layer configured to support the membrane over the chamber, to thereby enable the membrane to move fluid from the chamber or prevent the fluid from moving through the chamber.

25. The cavity substrate of claim 24 further comprising a silicon dioxide layer in between the first and second layers.

26. A of fabricating cavity substrate of a MEMS device that is configured as a valve with an inlet port to receive fluid and an outlet port to release the fluid within the valve, the method comprising:
depositing silicon dioxide onto a silicon layer to form a silicon dioxide layer;
patterning and etching the silicon dioxide layer using lithography and plasma etch to create a height of the valve;
patterning and etching the silicon layer to form a valve seat and a chamber of the cavity substrate;
patterning and etching the silicon layer to create the inlet and outlet ports of the cavity substrate;
fusion bonding a silicon on insulator wafer to the cavity substrate;
removing a handle wafer to expose the silicon layer as a membrane;
depositing a piezoelectric stack on silicon oxide layer, the piezoelectric stack includes a piezoelectric element and an electrode layer between the piezoelectric element and the silicon dioxide layer;
pattering and etching the piezoelectric (PZT) element;
patterning and etching the electrode layer up to the silicon dioxide layer;
depositing an interlayer dielectric layer (ILD) or passivation layer;
patterning the interlayer dielectric layer until it reaches the electrode layer and piezoelectric element;
depositing and patterning the electrode layer on top of the piezoelectric element and pads on bottom electrode layer;
electroplating gold pads are electroplated; and
back grinding, etching and polishing the silicon layer short of the opening in the silicon layer.
